(19) United States
(12) Patent Application Publication
(10) Pub. No.: US 2026/0122920 A1
(43) Pub. Date: Apr. 30, 2026

(54) SEMICONDUCTOR MEMORY DEVICE

(71) Applicant: SAMSUNG ELECTRONICS CO., LTD., Suwon-si (KR)

(72) Inventors: Byunggon Park, Suwon-si (KR); Jaeho Jeong, Suwon-si (KR); Bonghyun Choi, Suwon-si (KR); Soo-Sik Oh, Suwon-si (KR); Junbeom Park, Suwon-si (KR); Yongjoon Shin, Suwon-si (KR); Hyun Syek Oh, Suwon-si (KR); Taesu Yoon, Suwon-si (KR)

(21) Appl. No.: 19/197,576

(22) Filed: May 2, 2025

(30) Foreign Application Priority Data
Oct. 31, 2024 (KR) 10-2024-0152870

(51) Int. Cl. H10B 80/00; H01L 23/00; H01L 25/00; H01L 25/065; H01L 25/18

(52) U.S. Cl. CPC H10B 80/00; H10W 90/00; H10W 80/312; H10W 80/327; H10W 90/792

(57) ABSTRACT

Provided is a semiconductor memory device including a cell structure that includes a cell substrate, a mold structure including a plurality of gate electrodes stacked in a first direction on the cell substrate, a channel structure, and a cell bonding metal layer. The cell bonding metal layer includes a first cell bonding region including a plurality of first cell bonding metals disposed at a first interval along a second direction intersecting with the first direction and a second cell bonding region including a plurality of second cell bonding metals disposed at a second interval different from the first interval along the second direction, and the first cell bonding region and the second cell bonding region are disposed alternately along the second direction.

### CROSS-REFERENCE TO RELATED APPLICATION

This application claims the benefit of Korean Patent Application No. 10-2024-0152870, filed on Oct. 31, 2024, in the Korean Intellectual Property Office, the entirety of which is incorporated herein by reference.

### BACKGROUND

Based on a demand for a semiconductor memory device that may store high-capacity data in an electronic system, research on increasing the data storage capacity of the semiconductor memory device has been conducted. As one approach for increasing the data storage capacity of the semiconductor memory device, a semiconductor memory device including memory cells arranged three-dimensionally instead of memory cells arranged two-dimensionally is suggested.

To increase the data storage capacity of the semiconductor memory device, active research has been conducted recently on technologies for manufacturing the semiconductor memory device including memory cells arranged three-dimensionally, such as a vertical NAND (VNAND) flash memory device.

The semiconductor memory device is also evolving from a three-dimensional cell structure to a structure of vertically bonding a memory cell and a peripheral circuit.

### SUMMARY

When a defect arises in a memory cell and/or a peripheral circuit, a technology that locates and resolves the defect is significant in the technologies for manufacturing the semiconductor memory device. For purposes of this disclosure, it has been recognized that there is a need for a reference point to identify a location of a defect in the memory cell and the peripheral circuit.

Some aspects of the present disclosure provide semiconductor memory devices including a bonding metal layer where a pattern defining a specific location in a memory cell and/or a peripheral circuit is formed.

According to some implementations, there is provided a semiconductor memory device including a cell structure comprising a cell substrate, a mold structure including a plurality of gate electrodes stacked in a first direction on the cell substrate, a channel structure extending in the mold structure in the first direction, and a cell bonding metal layer disposed below the mold structure in the first direction and a peripheral circuit structure that includes a peripheral circuit substrate and a peripheral bonding metal layer connected to the cell bonding metal layer, and the peripheral circuit structure is located above the peripheral circuit substrate in the first direction and is connected to the cell structure at a bonding surface, and the cell bonding metal layer may include a plurality of first cell bonding regions, and each of the plurality of first cell bonding regions includes a plurality of first cell bonding metal portions disposed at a first interval along a second direction intersecting with the first direction and a plurality of second cell bonding regions, and each of the plurality of second cell bonding regions includes a plurality of second cell bonding metal portions disposed at a second interval different from the first interval along the second direction, and the plurality of first cell bonding regions and the plurality of second cell bonding regions may be disposed alternately along the second direction.

According to some implementations, there is provided a semiconductor memory device including a cell structure comprising a cell substrate, a mold structure including a plurality of gate electrodes stacked in a first direction on the cell substrate, a channel structure extending in the mold structure in the first direction, and a cell bonding metal layer disposed below the mold structure in the first direction and a peripheral circuit structure that includes a peripheral circuit substrate and a peripheral bonding metal layer that is connected to the cell bonding metal layer, and the peripheral circuit structure is located above the peripheral circuit substrate in the first direction and is connected to the cell structure at a bonding surface, and the cell bonding metal layer may include a plurality of first cell bonding regions, and each of the plurality of first cell bonding regions includes a plurality of first cell bonding metal portions disposed at a first predetermined interval along a second direction intersecting with the first direction and a plurality of second cell bonding regions, and each of the plurality of second cell bonding regions includes a plurality of second cell bonding metal portions disposed at a second predetermined interval along the second direction, and a ratio of an area of a plurality of second cell bonding metal portions in one of the plurality of second cell bonding regions, to an area of the one of the plurality of second cell bonding regions, is less than a ratio of an area of a plurality of first cell bonding metal portions in one of the plurality of first cell bonding regions, to an area of the one of the plurality of first cell bonding regions, and the plurality of first cell bonding regions and the plurality of second cell bonding regions may be disposed alternately along the second direction.

According to some implementations, there is provided a semiconductor memory device including a cell structure comprising a cell substrate, a mold structure including a plurality of gate electrodes stacked in a first direction on the cell substrate, a channel structure extending in the mold structure in the first direction, and a cell bonding metal layer disposed below the mold structure in the first direction and a peripheral circuit structure that includes a peripheral circuit substrate and a peripheral bonding metal layer that is connected to the cell bonding metal layer, and the peripheral bonding metal layer is located above the peripheral circuit substrate in the first direction and is connected to the cell structure at a bonding surface, and the cell bonding metal layer may include a plurality of first cell bonding regions, and each of the plurality of first cell bonding regions includes a plurality of first cell bonding metal portions disposed at a first interval along a second direction intersecting with the first direction, and the plurality of first cell bonding metal portions are electrically isolated from the channel structure, a plurality of second cell bonding regions, and each of the plurality of second cell bonding regions includes a plurality of second cell bonding metal portions disposed at a second interval smaller than the first interval, along the second direction, and the plurality of second cell bonding metal portions are electrically isolated from the channel structure, and a plurality of third cell bonding regions, and each of the plurality of third cell bonding regions includes a plurality of third cell bonding metal portions disposed at a third interval, smaller than the first interval, along the second direction, and the plurality of third cell bonding metal portions are electrically isolated from the channel structure, and the plurality of first cell bonding regions and the plurality of second cell bonding regions may be disposed alternately along the second direction, and the plurality of first cell bonding regions and the plurality of third cell bonding regions may be disposed alternately along a third direction intersecting with the first direction and intersecting with the second direction.

Based on the foregoing and/or other features described herein, in some implementations, it is possible to enhance the speed of detecting a location of a defect in a semiconductor memory device. According to some implementations, it is possible to enhance the accuracy of detecting a location of a defect in a semiconductor memory device. According to some implementations, it is possible to maintain a bonding force between a memory cell and a peripheral circuit in a semiconductor memory device without the degradation of electrical connection between the memory cell and the peripheral circuit.

### BRIEF DESCRIPTION OF THE FIGURES

These and/or other aspects, features, and advantages will become apparent and appreciated from the following description, taken in conjunction with the accompanying drawings, of which:

FIG. 1 is a block diagram illustrating an example of a semiconductor memory device;

FIG. 2 is a circuit diagram illustrating an example of a semiconductor memory device;

FIG. 3 is a schematic layout diagram illustrating an example of a semiconductor memory device;

FIG. 4 is a diagram illustrating an example of a cross-section taken along line A-A of FIG. 3;

FIG. 5 is a diagram illustrating a portion of an example of a semiconductor memory device;

FIG. 6 is an enlarged view illustrating an example of part R of FIG. 5;

FIG. 7 is a diagram illustrating a portion of a cell bonding metal layer of an example of a semiconductor memory device;

FIG. 8 is a diagram illustrating a portion of a cell bonding metal layer of an example of a semiconductor memory device;

FIGS. 9 to 15 are diagrams showing intermediate stages of an example of a method of manufacturing a semiconductor memory device;

FIG. 16 is a diagram illustrating a cross-section of a portion of an example of a semiconductor memory device;

FIG. 17 is a diagram illustrating an example of an electronic system including a semiconductor memory device;

FIG. 18 is a perspective view illustrating an example of an electronic system including a semiconductor memory device; and

FIG. 19 is a diagram illustrating an example of a cross-section taken along line I-I of FIG. 18.

### DETAILED DESCRIPTION

In the following description, a singular expression includes a plural expression unless apparently otherwise defined by context. It should be understood that terms such as “comprise or include” and “form or configure” are intended to indicate the presence of a feature, a number, a step, an operation, an element, a component, or a combination thereof which are described in the specification and not intended to exclude the possibility of the presence or addition of one or more other features, numbers, steps, operations, elements, components, or combinations thereof.

In addition, although the terms such as first and second may be used to describe various elements, those terms may be used to distinguish one element from another without suggesting any ordering therein. Within the scope of the present disclosure, a first element may be referred to as a second element, and similarly, a second element may be referred to as a first element. Further, the shape or size of elements in the accompanying drawings may be exaggerated for clearer description.

In addition, expressions such as upper side, upper portion, above, lower side, lower portion, below, side surface, front side, and back side hereinafter are represented with respect to a direction illustrated in a drawing and may be represented otherwise when the direction of a corresponding object changes.

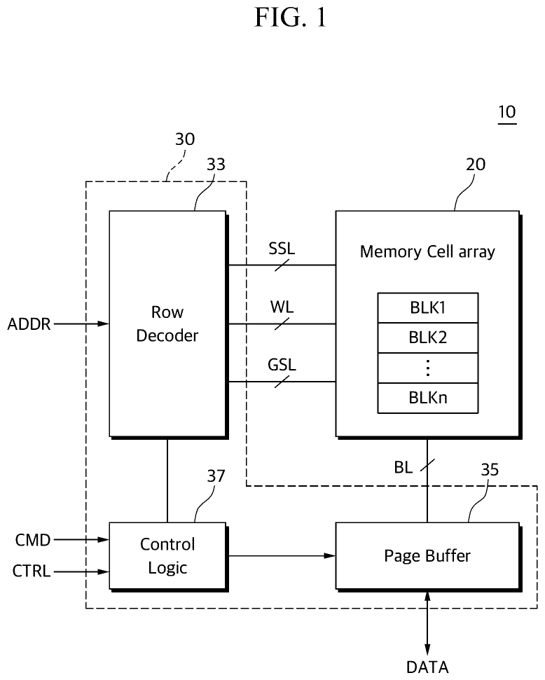

FIG. 1 is a block diagram for illustrating a semiconductor memory device 10 according to some implementations of the present disclosure. Referring to FIG. 1, the semiconductor memory device 10 may include a memory cell array 20 and a peripheral circuit 30.

In some implementations, the memory cell array 20 may include a plurality of memory cell blocks BLK1 to BLKn. Each of the memory cell blocks BLK1 to BLKn may include a plurality of memory cells. The memory cell array 20 may be connected to the peripheral circuit 30 through a bit line BL, a word line WL, at least one string selection line SSL, and at least one ground selection line GSL. For example, the memory cell blocks BLK1 to BLKn may be connected to a row decoder 33 through the word line WL, the string selection line SSL, and the ground selection line GSL. In addition, the memory cell blocks BLK1 to BLKn may be connected to a page buffer 35 through the bit line BL.

In some implementations, the peripheral circuit 30 may receive an address ADDR, a command CMD, and a control signal CTRL from outside of the semiconductor memory device 10 and may transmit and receive data DATA to and from a device outside the semiconductor memory device 10. The peripheral circuit 30 may include a control logic 37, the row decoder 33, and the page buffer 35. The peripheral circuit 30 may further include various sub-circuits such as an input/output circuit, a voltage generation circuit generating various voltages for operating the semiconductor memory device 10, and an error correction circuit for correcting errors in the data DATA read from the memory cell array 20.

In some implementations, the control logic 37 may be connected to the row decoder 33, the input/output circuit, and the voltage generation circuit. The control logic 37 may control the overall operation of the semiconductor memory device 10. The control logic 37 may generate various internal control signals used within the semiconductor memory device 10 in response to the control signal CTRL. For example, the control logic 37 may regulate a level of voltage provided to the word line WL and the bit line BL when a memory operation such as a program operation or an erase operation is performed.

In some implementations, the row decoder 33 may select at least one of the plurality of memory cell blocks BLK1 to BLKn in response to the address ADDR and may select at least one word line WL, at least one string selection line SSL, and at least one ground selection line GSL of the selected memory cell block BLK1 to BLKn. In addition, the row decoder 33 may transmit voltage for performing the memory operation to the word line WL of the selected memory cell block BLK1 to BLKn.

In some implementations, the page buffer 35 may be connected to the memory cell array 20 through the bit line BL. The page buffer 35 may operate as a writer driver or a sense amplifier. For example, when the program operation is performed, the page buffer 35 may operate as the writer driver and apply voltage according to the data DATA to be stored in the memory cell array 20 to the bit line BL. When a read operation is performed, the page buffer 35 may operate as the sense amplifier and sense the data DATA stored in the memory cell array 20.

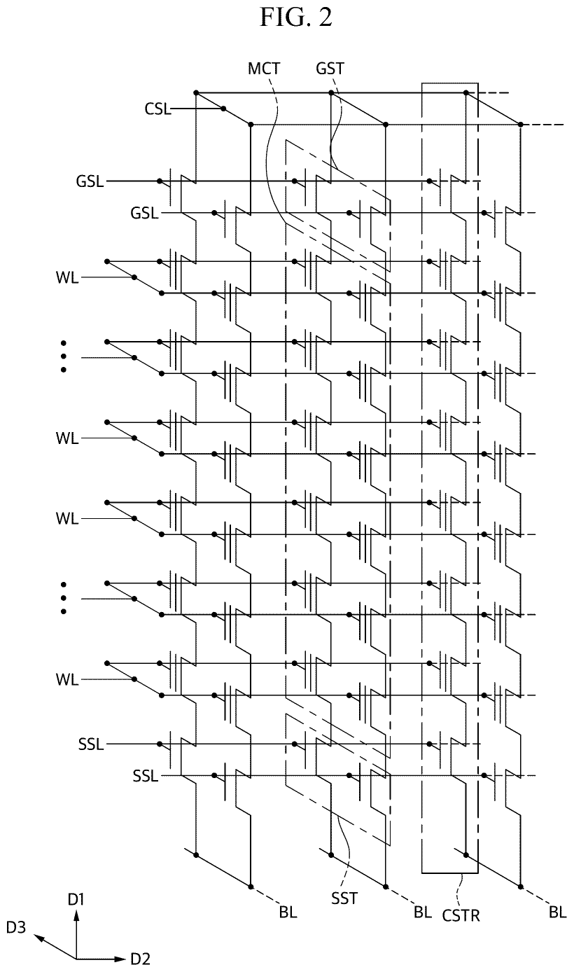

FIG. 2 is a circuit diagram illustrating an example of the semiconductor memory device 10. Referring to FIG. 2, a memory cell array (for example, 20 of FIG. 1) of the semiconductor memory device 10 may include a common source line CSL, a plurality of bit lines BL, and a plurality of cell strings CSTR.

In some implementations, the plurality of bit lines BL may be arranged two-dimensionally in a plane including a second direction D2 and a third direction D3. For example, each of the bit lines BL may extend in the third direction D3 and may be spaced apart from each other and arranged along the second direction D2. The plurality of cell strings CSTR may be connected in parallel to each of the bit lines BL. The cell strings CSTR may be connected in common to the common source line CSL. For example, the plurality of cell strings CSTR may be disposed between the bit line BL and the common source line CSL. The plurality of cell strings CSTR may extend in a first direction D1.

In some implementations, each of the plurality of cell strings CSTR may include a ground selection transistor GST connected to the common source line CSL, a string selection transistor SST connected to the bit line BL, and a plurality of memory cell transistors MCT disposed between the ground selection transistor GST and the string selection transistor SST. Each of the memory cell transistors MCT may include a data storage element. The ground selection transistor GST, the string selection transistor SST, and the memory cell transistors MCT may be connected in series.

In some implementations, the common source line CSL may be connected in common to sources of the ground selection transistors GST. In addition, the ground selection line GSL, a plurality of word lines WL, and the string selection line SSL may be disposed between the common source line CSL and the bit line BL. The ground selection line GSL may be used as a gate electrode of the ground selection transistor GST, the plurality of word lines WL may be used as a gate electrode of the memory cell transistors MCT, and the string selection line SSL may be used as a gate electrode of the string selection transistor SST.

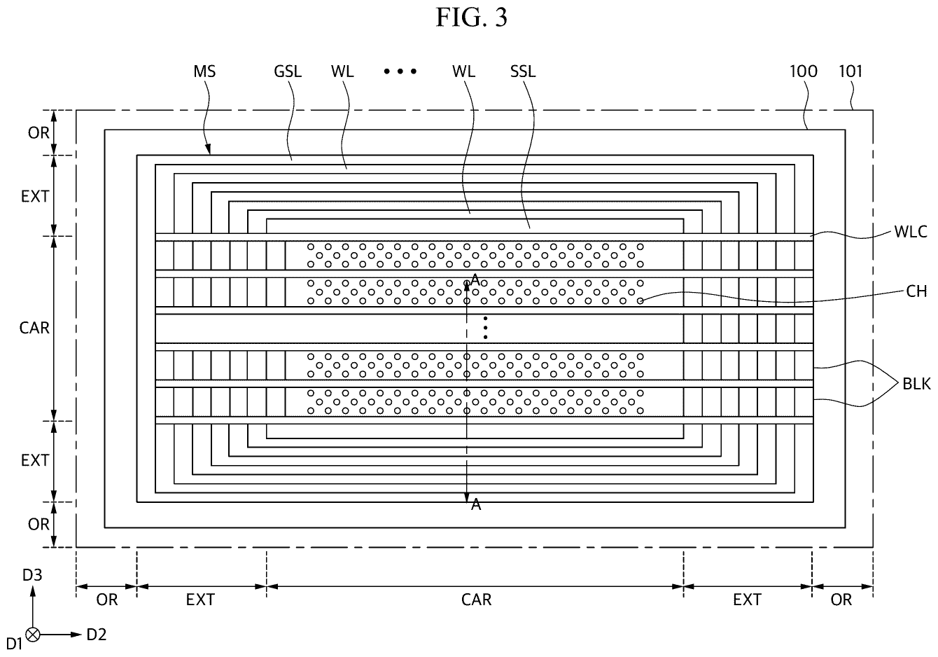

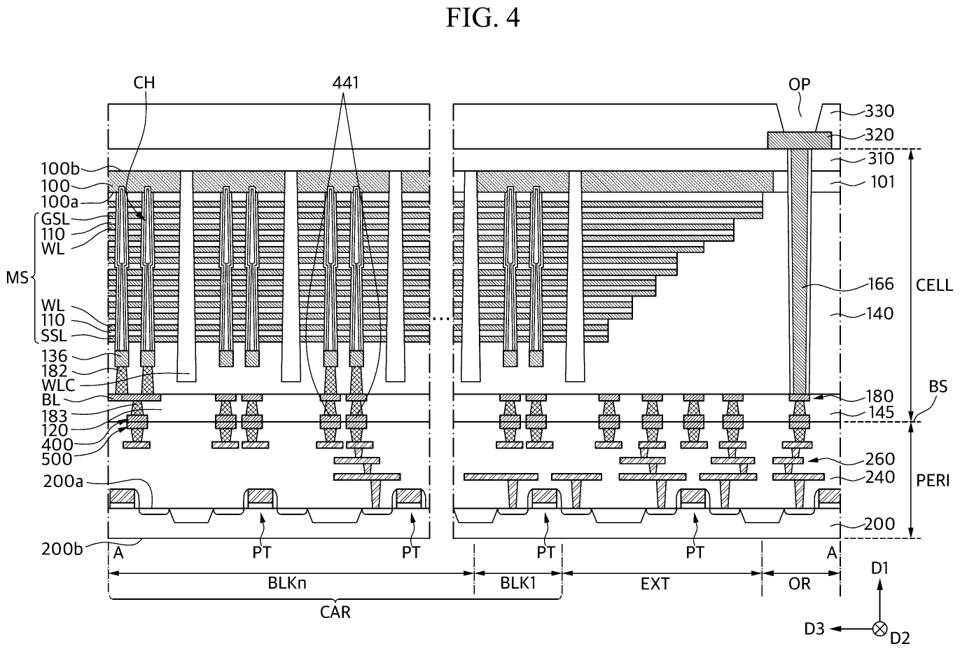

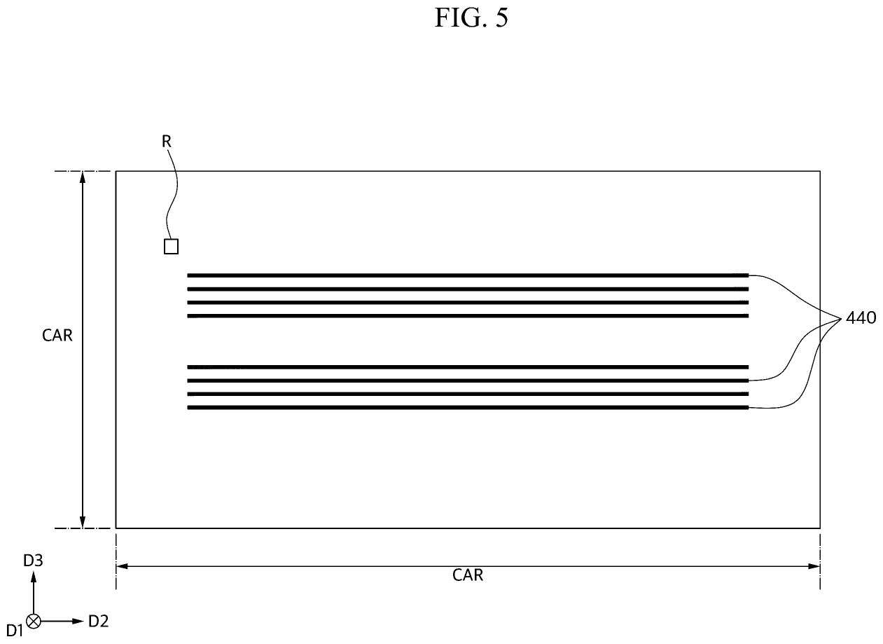

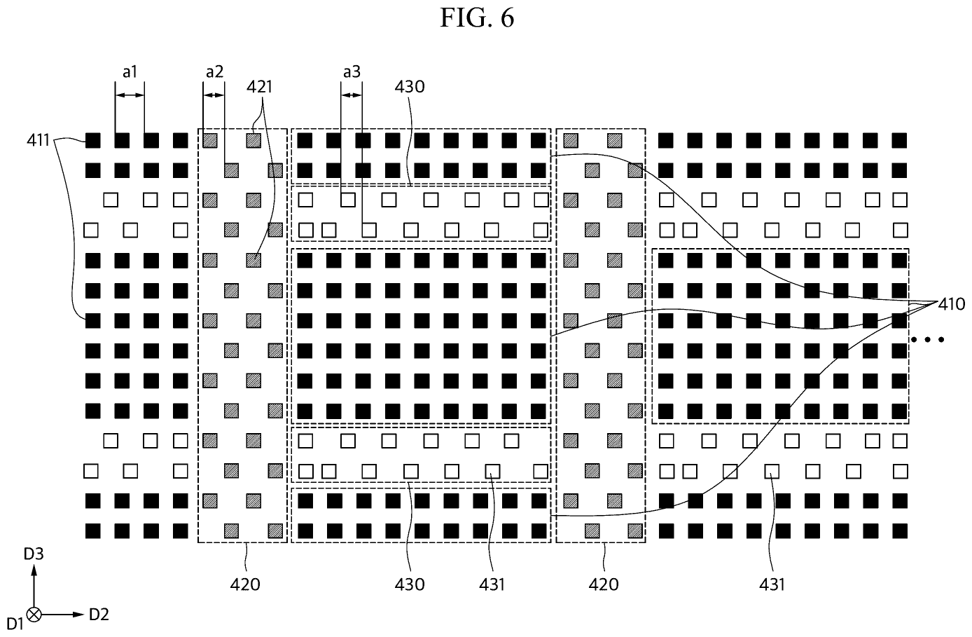

FIG. 3 is a schematic layout diagram for illustrating an example of the semiconductor memory device 10, FIG. 4 is a diagram illustrating a cross-section taken along line A-A of FIG. 3, FIG. 5 is a diagram illustrating an example of a portion of the semiconductor memory device 10, and FIG. 6 is an enlarged view illustrating part R of FIG. 5.

Referring to FIGS. 3 to 6, the semiconductor memory device 10 may include a cell structure CELL and a peripheral circuit structure PERI, and the cell structure CELL may include a cell substrate 100, an insulating substrate 101, a mold structure MS, a first interlayer insulating layer 140, a gate electrode cutting line WLC, a channel structure CH, the bit line BL, a capacitor structure CAP, and a cell wiring structure 180. Although the capacitor structure CAP is not illustrated in FIG. 3, the capacitor structure CAP may be disposed at a portion of an area where the channel structure CH is disposed.

In some implementations, the cell substrate 100 may include a semiconductor substrate such as a silicon substrate, a germanium substrate, or a silicon-germanium substrate. The cell substrate 100 may include a silicon-on-insulator (SOI) substrate or a germanium-on-insulator (GOI) substrate.

In some implementations, the cell substrate 100 may include an impurity. For example, the cell substrate 100 may include an n-type impurity (for example, phosphorus (P) and arsenic (As)). However, impurities are not limited thereto. For example, the cell substrate 100 may include a p-type impurity. The cell substrate 100 may include polysilicon (poly-Si) doped with the n-type impurity. The cell substrate 100 may be provided as a common source line (for example, CSL of FIG. 2) of the semiconductor memory device 10.

In some implementations, the cell substrate 100 may include a cell array region CAR and an extension region EXT.

In some implementations, a memory cell array (for example, 20 of FIG. 1) including a plurality of memory cells may be formed in the cell array region CAR. For example, the channel structure CH, the bit line BL, and a plurality of gate electrodes GSL, WL, and SSL to be described below may be disposed in the cell array region CAR. A surface of the cell substrate 100 on which the memory cell array is disposed may be referred to as a first surface 100a of the cell substrate. The first surface 100a of the cell substrate may be a front side of the cell substrate 100. In contrast, a surface of the cell substrate 100 opposite to the first surface 100a of the cell substrate may be referred to as a second surface 100b of the cell substrate. The second surface 100b of the cell substrate may be a back side of the cell substrate 100.

In some implementations, the gate electrode cutting line WLC may extend in the first direction D1. Specifically, the gate electrode cutting line WLC may extend along a plane including the first direction D1 and the second direction D2. The gate electrode cutting line WLC may extend from the cell substrate 100 in the first direction D1 and cut the plurality of gate electrodes GSL, WL, and SSL. The gate electrode cutting line WLC may cut, along the plane including the first direction D1 and the second direction D2, and separate the plurality of gate electrodes GSL, WL, and SSL into a plurality of blocks. The gate electrode cutting line WLC may include an insulation material, for example, at least one of silicon oxide, silicon nitride, and silicon oxynitride, but is not limited thereto.

In some implementations, the gate electrode cutting line WLC may extend in the second direction D2. The gate electrode cutting line WLC may extend across the cell array region CAR and the extension region EXT. For example, the gate electrode cutting line WLC may extend across the cell array region CAR and the extension region EXT disposed adjacent to the cell array region CAR in the second direction D2.

In some implementations, the gate electrode cutting lines WLC may be spaced apart from one another in the third direction D3. The gate electrode cutting lines WLC may extend in the second direction D2 parallel to one another. The gate electrode cutting lines WLC may separate the mold structure MS into a plurality of memory cell blocks BLK1 to BLKn in the third direction D3. The plurality of memory cell blocks BLK1 to BLKn may be disposed in the third direction D3. The gate electrode cutting line WLC may be disposed between two of the plurality of memory cell blocks BLK1 to BLKn adjacent to each other. Each of the plurality of memory cell blocks BLK1 to BLKn may be disposed between two gate electrode cutting lines WLC adjacent in the third direction D3.

In some implementations, the extension region EXT may be disposed around the cell array region CAR. For example, the extension region EXT may surround the cell array region CAR in a plan view or be on two opposite sides of the cell array region CAR in the plan view. The plurality of gate electrodes GSL, WL, and SSL to be described below may be stacked in a stepped manner in the extension region EXT.

In some implementations, the insulating substrate 101 may be formed around the cell substrate 100. The insulating substrate 101 may form an insulation region around the cell substrate 100. For example, the insulating substrate 101 may include, but is not limited to, at least one of silicon oxide, silicon nitride, silicon oxynitride, and silicon carbide.

In some implementations, the cell substrate 100 and the insulating substrate 101 may further include an outer region OR. The outer region OR may be disposed outside the cell array region CAR and the extension region EXT. For example, the outer region OR may surround the cell array region CAR and the extension region EXT in a plan view.

In some implementations, the mold structure MS may be formed on the first surface 100a of the cell substrate. The mold structure MS may include the plurality of gate electrodes GSL, WL, and SSL and a plurality of mold insulating layers 110 stacked on the cell substrate 100. Each of the plurality of gate electrodes GSL, WL, and SSL and each of the plurality of mold insulating layers 110 may have a layered structure extending in parallel to the first surface 100a of the cell substrate. The plurality of gate electrodes GSL, WL, and SSL may be spaced apart from each other by the mold insulating layers 110 and stacked on the first surface 100a of the cell substrate in sequence. It is illustrated that the plurality of gate electrodes GSL, WL, and SSL only include one ground selection line GSL and one string selection line SSL, but implementations are not limited thereto. For example, the plurality of gate electrodes GSL, WL, and SSL may include two or more ground selection lines and two or more string selection lines.

In some implementations, the mold structure MS may include a first mold structure and a second mold structure which are stacked on the first surface 100a of the cell substrate in sequence. The channel structure CH may have a bent part between the first mold structure and the second mold structure. For example, the first mold structure may include first gate electrodes GSL and WL and the mold insulating layer 110 which are stacked alternately on the cell substrate 100. In some implementations, the first gate electrodes GSL and WL may include the ground selection line GSL and the word line WL which are stacked on the cell substrate 100 in sequence. The second mold structure may include second gate electrodes WL and SSL and the mold insulating layer 110 which are stacked alternately on the first mold structure. The second gate electrodes WL and SSL may include the word line WL and the string selection line SSL which are stacked on the first mold structure in sequence.

In some implementations, each of the plurality of gate electrodes GSL, WL, and SSL may include, but is not limited to, a conductive material, for example, a metal such as tungsten (W), cobalt (Co), and nickel (Ni) or a semiconductor material such as silicon.

In some implementations, each of the mold insulating layers 110 may include an insulation material. For example, the mold insulating layers 110 may include, but are not limited to, at least one of silicon oxide, silicon nitride, and silicon oxynitride.

In some implementations, the first interlayer insulating layer 140 may be formed on the first surface 100a of the cell substrate and/or the insulating substrate 101 and cover the mold structure MS. For example, the first interlayer insulating layer 140 may include, but is not limited to, at least one of silicon oxide, silicon oxynitride, and a low-permittivity (low-k) material having lower permittivity than silicon oxide.

In some implementations, the channel structure CH may be formed within the mold structure MS of the cell array region CAR. The channel structure CH may extend in the first direction D1 perpendicular to the first surface 100a of the cell substrate and penetrate the mold structure MS. The channel structure CH may be disposed in at least one of the plurality of memory cell blocks (BLK1˜BLKn). The channel structure CH may penetrate the mold structure MS in the first direction D1 within at least one of the plurality of memory cell blocks (BLK1-BLKn). For example, the channel structure CH may have a pillar shape (for example, a cylindrical shape) extending in the first direction D1. Accordingly, the channel structure CH may intersect with each of the plurality of gate electrodes GSL, WL, and SSL. The channel structure CH may have a bent part within the mold structure MS. For example, the channel structure CH may have the bent part between the first mold structure and the second mold structure. The channel structure CH may have a step between the first mold structure and the second mold structure.

In some implementations, the channel structure CH may be disposed within a channel hole penetrating the mold structure MS. The channel hole may penetrate the mold structure MS on the first surface 100a of the cell substrate. The channel structure CH may be arranged in a zigzag form. For example, the channel structure CH may be arranged to be staggered in the second direction D2 and the third direction D3 parallel to an upper surface of the cell substrate 100. A plurality of channel structures CH arranged in the zigzag form may improve the integration density of the semiconductor memory device 10. The plurality of channel structures CH may be arranged in a honeycomb form.

In some implementations, the channel structure CH may further include a channel pad 136. The channel pad 136 may be formed to be connected to an end (for example, a lower end) of a semiconductor pattern. The channel pad 136 may include a conductive material, for example, polysilicon doped with an impurity or metal, but is not limited thereto.

In some implementations, the bit line BL may be formed above the mold structure MS. The bit line BL may extend in the third direction D3 and intersect with the gate electrode cutting line WLC. The bit line BL may extend in the third direction D3 to be connected to the plurality of channel structures CH arranged along the third direction D3. For example, a bit line contact 182 connected to an upper portion of each of the channel structures CH may be formed within the first interlayer insulating layer 140. The bit line BL may be electrically connected to the channel structure CH through the bit line contact 182.

In some implementations, the peripheral circuit structure PERI may include a peripheral circuit substrate 200, a peripheral circuit element PT, and a peripheral circuit wiring structure 260.

In some implementations, the peripheral circuit substrate 200 may be disposed below the cell substrate 100. For example, the peripheral circuit substrate 200 may face the first surface 100a of the cell substrate. For example, the peripheral circuit substrate 200 may include a semiconductor substrate such as a silicon substrate, a germanium substrate, or a silicon-germanium substrate. For example, the peripheral circuit substrate 200 may also include a silicon-on-insulator (SOI) substrate or a germanium-on-insulator (GOI) substrate.

In some implementations, the peripheral circuit element PT may be formed on the peripheral circuit substrate 200. The peripheral circuit element PT may configure, provide, or include a peripheral circuit (for example, 30 of FIG. 1) that controls the operation of the semiconductor memory device 10. For example, the peripheral circuit element PT may include a control logic (for example, 37 of FIG. 1), a row decoder (for example, 33 of FIG. 1), and a page buffer (for example, 35 of FIG. 1). Hereinafter, a surface of the peripheral circuit substrate 200 where the peripheral circuit element PT is disposed may be referred to as a first surface 200a of the peripheral circuit substrate. The first surface 200a of the peripheral circuit substrate may be a front side of the peripheral circuit substrate 200. In contrast, a surface of the peripheral circuit substrate 200 opposite to the first surface 200a of the peripheral circuit substrate may be referred to as a second surface 200b of the peripheral circuit substrate. The second surface 200b of the peripheral circuit substrate may be a back side of the peripheral circuit substrate 200.

In some implementations, the peripheral circuit element PT may include a transistor. In addition, the peripheral circuit element PT may include not only various active elements such as the transistor but also various passive elements such as a capacitor, a resistor, and an inductor. However, the configuration of the peripheral circuit element PT is not limited thereto.

In some implementations, the cell structure CELL may be stacked on the peripheral circuit structure PERI. For example, the cell structure CELL may be stacked on a second interwiring insulating layer 240.

In some implementations, the first surface 100a of the cell substrate may face the peripheral circuit structure PERI. For example, the first surface 100a of the cell substrate may face the first surface 200a of the peripheral circuit substrate.

In some implementations, the semiconductor memory device 10 may have a chip-to-chip (C2C) structure. The semiconductor memory device 10 may include an upper chip in which the cell structure CELL is formed on a first wafer (for example, the cell substrate 100). The semiconductor memory device 10 may include a lower chip in which the peripheral circuit structure PERI is formed on a second wafer (for example, the peripheral circuit substrate 200). The semiconductor memory device 10 may be fabricated by connecting the upper chip and the lower chip to each other in a bonding manner.

In some implementations, the semiconductor memory device 10 may include a cell bonding metal layer 400 and a peripheral bonding metal layer 500. The cell bonding metal layer 400 may be formed at an uppermost metal layer of the upper chip. The peripheral bonding metal layer 500 may be formed at an uppermost metal layer of the lower chip. A portion of the cell bonding metal layer 400 and a portion of the peripheral bonding metal layer 500 may be electrically connected to each other. For example, when bonding metals 411, 421, 431, and 441 of the cell bonding metal layer 400 and bonding metals 411, 421, 431, and 441 of the peripheral bonding metal layer 500 are formed of copper (Cu), the bonding manner may be a Cu—Cu bonding manner. However, this is merely an example, and the cell bonding metal layer 400 and the peripheral bonding metal layer 500 may also include other various metals such as aluminum (Al) or tungsten (W).

In some implementations, the semiconductor memory device 10 may include a bonding via 183. The bonding via 183 may be formed above the cell bonding metal layer 400 in the cell structure CELL. The bonding via 183 may be disposed within a first interwiring insulating layer 145. The bonding via 183 may connect the bit line BL and the cell bonding metal layer 400. The bonding via 183 may include a conductive material, for example, copper (Cu).

In some implementations, the cell wiring structure 180 may be connected to the peripheral circuit wiring structure 260 as the cell bonding metal layer 400 and the peripheral bonding metal layer 500 are bonded. Through this, the bit line BL, each of the gate electrodes GSL, WL, and SSL, and/or the cell substrate 100 may be electrically connected to the peripheral circuit element PT.

In some implementations, the cell wiring structure 180 and the cell bonding metal layer 400 may be formed within the first interwiring insulating layer 145. However, the present disclosure is not limited thereto. For example, the first interwiring insulating layer 145 may be formed on the first interlayer insulating layer 140, and the cell wiring structure 180 may be formed within the first interwiring insulating layer 145.

In some implementations, the semiconductor memory device 10 may include a second interlayer insulating layer 310, an input/output pad 320, a capping insulating layer 330, and a contact plug 166.

In some implementations, the second interlayer insulating layer 310 may be positioned on the second surface 100b of the cell substrate 100 to cover the cell substrate 100 and the insulating substrate 101. The input/output pad 320 may be formed on the second interlayer insulating layer 310. For example, the second interlayer insulating layer 310 may include, but is not limited to, at least one of silicon oxide, silicon oxynitride, and a low-permittivity (low-k) material having lower permittivity than silicon oxide.

In some implementations, the input/output pad 320 may be disposed on the second surface 100b of the cell substrate 100. The input/output pad 320 may be electrically connected to the cell structure CELL and/or the peripheral circuit structure PERI. The input/output pad 320 may be electrically connected to the cell wiring structure 180 through the contact plug 166.

In some implementations, the contact plug 166 may be formed in such a manner that the width of the contact plug 166 decreases toward the cell wiring structure 180. The shape of the contact plug 166 may originate from a characteristic of an etching process for forming the contact plug 166.

In some implementations, on a side surface of the contact plug 166, an insulating spacer extending along the side surface of the contact plug 166 may be formed. For example, the insulating spacer may surround the side surface of the contact plug 166. For example, the insulating spacer may include, but is not limited to, at least one of silicon oxide, silicon nitride, and silicon oxynitride.

In some implementations, the capping insulating layer 330 may be formed on the second interlayer insulating layer 310. The capping insulating layer 330 may include a pad opening OP that exposes at least a portion of the input/output pad 320. The input/output pad 320 may be electrically connected to an external device through the pad opening OP.

In some implementations, the cell bonding metal layer 400 may be formed within the first interwiring insulating layer 145. Some 441 of the bonding metals of the cell bonding metal layer 400 may be electrically connected to the channel structure CH. For example, a portion of the cell bonding metal layer 400 may be connected to the input/output pad 320 through the contact plug 166. For example, a portion of the cell bonding metal layer 400 may be connected to the bit line BL through the bonding via 183 and connected to the channel structure CH.

In some implementations, the semiconductor memory device 10 may include a channel bonding region 440. The channel bonding region 440 may be included within the cell array region CAR. The channel structure CH may generate a current flow. The channel structure CH may be connected to the cell bonding metal layer 400 through the channel pad 136, the bit line contact 182, the bit line BL, and the bonding via 183. The channel structure CH may be electrically connected to the peripheral circuit wiring structure 260 as the cell bonding metal layer 400 and the peripheral bonding metal layer 500 are connected and thus the cell structure CELL and the peripheral circuit structure PERI are electrically connected. However, all of the plurality of channel structures CH may not be electrically connected to the peripheral circuit structure PERI.

In some implementations, the cell array region CAR may include a portion where the channel structure CH is electrically connected to the cell bonding metal layer 400 and a portion where the channel structure CH is electrically isolated from the cell bonding metal layer 400. When a defect arises in the cell array region CAR at a configuration of the semiconductor memory device 10, a reference point for locating the defect may be used. For example, the increased integration density of the semiconductor memory device 10 may make counting for locating the defect difficult, and to resolve this, the number of reference points for counting may be decreased. For example, bonding metals may be counted one by one without a reference point, but with the reference point, a plurality of bonding metals may be counted at once, which may decrease the speed of locating the defect.

Accordingly, a pattern as a reference point for counting a location of a defect in the channel bonding region 440 may be formed at the portion where the channel structure CH is electrically isolated from the cell bonding metal layer 400, of which design is more freely changeable due to the electrical insulation than the portion where the channel structure CH is electrically connected to the cell bonding metal layer 400. By forming the pattern as the reference point for counting the location of the defect in the channel bonding region 440 at the portion where the channel structure CH is electrically isolated from the cell bonding metal layer 400, which is relatively larger than the portion where the channel structure CH is electrically connected to the cell bonding metal layer 400, the reference point that may define the location of the defect in the channel bonding region 440 may be formed. For example, in order that a grid pattern is formed along the second direction D2 and the third direction D3 in the cell array region CAR, the pattern as the reference point for counting the location of the defect in the channel bonding region 440 may be formed at the portion where the channel structure CH is electrically isolated from the cell bonding metal layer 400. For example, a portion or region including a plurality of channel bonding metals 441 electrically connected to the channel structure CH may be referred to as the channel bonding region 440. For example, a first cell bonding metal 411 of a first cell bonding region 410, a second cell bonding metal 421 of a second cell bonding region 420, and a third cell bonding metal 431 of a third cell bonding region 430 may be electrically isolated from the channel structure CH.

In some implementations, the cell bonding metal layer 400 may form a grid pattern on the cell array region CAR. For example, the second cell bonding region 420 may form or include a pattern extending in the third direction D3. The second cell bonding region 420 may form or include a pattern of elements (e.g., metal portions) disposed to be spaced apart from one another at a predetermined interval along the second direction D2. For example, the third cell bonding region 430 may form or include a pattern extending in the second direction D2. The third cell bonding region 430 may form or include a pattern of elements (e.g., metal portions) disposed to be spaced apart from one another at a predetermined interval along the third direction D3.

In some implementations, the densities of the bonding metals 411 and 421 included in the first cell bonding region 410 and the second cell bonding region 420 may be formed as different from each other. In addition, the densities of the bonding metals 411 and 431 included in the first cell bonding region 410 and the third cell bonding region 430 may be formed as different from each other. For example, a ratio of an area of a portion where the second cell bonding metal 421 is disposed in the second cell bonding region 420 and a ratio of an area of a portion where the third cell bonding metal 431 is disposed in the third cell bonding region 430 may be different from a ratio of an area of a portion where the first cell bonding metal 411 is disposed in the first cell bonding region 410. In other words, the spatial density of the second cell bonding metal 421 in the second cell bonding region 420 and the spatial density of the third cell bonding metal 431 in the third cell bonding region 430 may be different from the spatial density of the first cell bonding metal 411 in the first cell bonding region 410. However, the shape of a pattern formed in the cell bonding metal layer 400, a method of forming the pattern, and the spatial densities are not limited thereto.

Hereinafter, an example of a method of forming a pattern by changing the intervals and arrangements of the bonding metals 411, 421, 431, and 441 is described.

Referring to FIG. 6, the bonding metals 411, 421, and 431 formed in the cell bonding metal layer 400 may be disposed along a plane including or defined by the second direction D2 and the third direction D3. For example, the cell bonding metal layer 400 may include the first cell bonding region 410, the second cell bonding region 420, the third cell bonding region 430, and the channel bonding region 440.

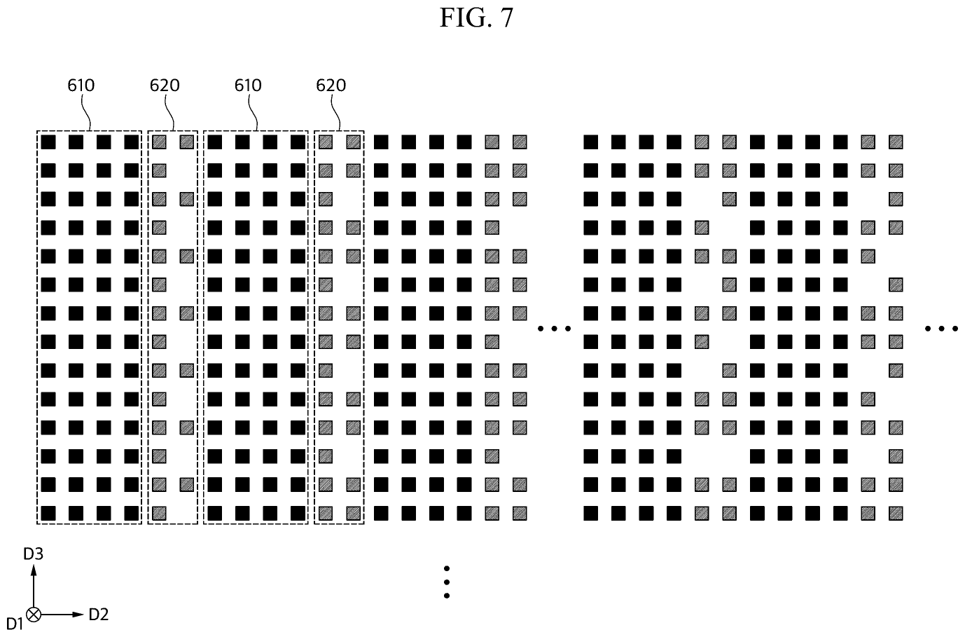

In some implementations, the bonding metals 411, 421, and 431 formed in the cell bonding metal layer 400 may be disposed in a specific pattern. A pattern in which the bonding metals 411, 421, and 431 is disposed may indicate or identify different ones of the second cell bonding regions 420. For example, different second cell bonding regions 420 may include second cell bonding metals 421 disposed in different patterns. As such, an index or identity of each of the second cell bonding regions 420 can be identified more readily. For example, an N-th of the second cell bonding regions 420 can have a pattern of second cell bonding metals 421 that indicates that the N-th second cell bonding region 420 is the N-th second cell bonding region 420 (e.g., in a sequence starting with a first second cell bonding region 420). This is shown further in FIG. 7, in which different ones of the second cell bonding regions 620 have different patterns of second cell bonding metals.

In some implementations, the first cell bonding regions 410 may be disposed at predetermined interval(s) along the second direction D2 and the third direction D3. Each of the first cell bonding regions 410 may form a region of a grid pattern. For example, the first cell bonding regions 410 may together define a grid pattern of quadrilateral regions, with spaces in-between. For example, a plurality of first cell bonding regions 410 may form a structure in which a plane is partitioned into a plurality of quadrilateral regions when viewed in a plan view. The second cell bonding region 420 and the third cell bonding region 430 may be disposed in the spaces between the first cell bonding regions 410 in the grid pattern, e.g., between adjacent ones of the plurality of first cell bonding regions 410. However, the form and the size of the first cell bonding regions 410 are not limited to the above description and the drawings.

In some implementations, each first cell bonding region 410 may be surrounded by a second cell bonding region 420 and a third cell bonding region 430, excluding the first cell bonding region 410 which is outermost. For example, the first cell bonding region 410 may be disposed in such a manner that a border of the first cell bonding region 410 is adjacent to the second cell bonding region 420 and the third cell bonding region 430.

In some implementations, the cell bonding metal layer 400 may include first cell bonding metals (or portion of metal) 411 disposed in each of the first cell bonding regions 410. The first cell bonding metals 411 may be disposed in a plural number in each first cell bonding region 410. The first cell bonding metals 411 may be connected to the peripheral bonding metal layer 500 and may be formed of copper (Cu). However, this is merely an example, and the first cell bonding metal 411 may also be formed of other various metals such as aluminum (Al) or tungsten (W). The first cell bonding metals 411 may be discrete portions of metal that are discontinuous from one another.

In some implementations, the first cell bonding metals 411 may be arranged two-dimensionally (e.g., forming a two-dimensional array, or other two-dimensional pattern) within the first cell bonding region 410. The first cell bonding metals 411 may be disposed to be spaced apart from each other within the first cell bonding region 410. For example, the first cell bonding metals 411 may be disposed at a first interval a1 along the second direction D2 and disposed at a predetermined interval along the third direction D3. As shown in FIG. 6, an interval can refer to a spatial period of the first cell bonding metals 411 or a distance between corresponding edges of first cell bonding metals 411 that are consecutive to one another along the second direction D2 or third direction D3.

In some implementations, the second cell bonding regions 420 may be disposed at a predetermined interval along the second direction D2. A plurality of second cell bonding regions 420 may form a structure in which a plane is partitioned into a plurality of quadrilateral regions arranged along the second direction D2 when viewed in a plan view. The first cell bonding regions 410 and the third cell bonding regions 430 may be disposed between adjacent ones of the plurality of second cell bonding regions 420. For example, the second cell bonding regions 420 may be disposed in such a manner that a border of each second cell bonding region 420 is adjacent to the first cell bonding region 410 and the third cell bonding region 430. However, the form and the size of the second cell bonding region 420 are not limited to the above description and the drawings.

In some implementations, the cell bonding metal layer 400 may include second cell bonding metals (or metal portions) 421 disposed in each of the second cell bonding regions 420. The second cell bonding metals 421 may be disposed in a plural number in each second cell bonding region 420. The second cell bonding metals 421 may be connected to the peripheral bonding metal layer 500 and may be formed of copper (Cu). However, this is merely an example, and the second cell bonding metal 421 may also be formed of other various metals such as aluminum (Al) or tungsten (W). The second cell bonding metals 421 may be discrete portions of metal that are discontinuous from one another.

In some implementations, the second cell bonding metals 421 may be arranged two-dimensionally within the second cell bonding region 420 (e.g., forming a two-dimensional array, or other two-dimensional pattern). The second cell bonding metals 421 may be disposed to be spaced apart from each other within each second cell bonding region 420. For example, at least some of the second cell bonding metals 421 may be disposed at a second interval a2 along the second direction D2 and disposed at a predetermined interval along the third direction D3.

In some implementations, at least some of the second cell bonding metals 421 may be disposed in a zigzag or staggered manner along the third direction D3. For example, at least some of the second cell bonding metals 421 may be disposed to be staggered along the third direction D3. As the second cell bonding metals 421 are disposed to be staggered, an area of a portion occupied by the second cell bonding metal 421 in the second cell bonding region 420 may decrease. Due to this, a ratio of an area of the plurality of second cell bonding metals 421 to an area of the second cell bonding region 420 may be less than a ratio of an area of the plurality of first cell bonding metals 411 to an area of the first cell bonding region 410. Accordingly, when the cell array region CAR is observed through a transmission electron microscope (TEM), the second cell bonding region 420 may appear fainter on the cell array region CAR than the first cell bonding region 410. The bonding metals 411 and 421 of the first cell bonding region 410 and the second cell bonding region 420 may form respective pluralities of vertical patterns parallel to the third direction D3 on the cell array region CAR, the vertical patterns spaced apart at a predetermined interval along the second direction D2. Since the second cell bonding metals 421 are disposed in a zigzag manner (e.g., and as a result of a difference between the densities of the bonding metals 411 and 421), an interval between second cell bonding metals 421 adjacent in an identical or vertical line may increase or may be larger than an interval between first cell bonding metals 411 adjacent in an identical or vertical line. Accordingly, a defect may arise in the manufacturing process of forming the cell bonding metal layer 400. In some implementations, to prevent or reduce occurrence of these defects, the second interval a2 may be smaller than the first interval a1.

In some implementations, the plurality of vertical patterns formed by the second cell bonding region 420 may be parallel to the third direction D3. The plurality of vertical patterns formed by the second cell bonding region 420 may be disposed to be spaced apart from each other along the second direction D2.

In some implementations, the third cell bonding regions 430 may be disposed at a predetermined interval along the third direction D3 (and, in some implementations, the second direction D2). Each of the third cell bonding regions 430 may form a region of a grid pattern. For example, the third cell bonding regions 430 may together define a grid pattern of quadrilateral regions, with spaces in-between. For example, a plurality of third cell bonding regions 430 may form a structure in which a plane is partitioned into a plurality of quadrilateral regions arranged along the third direction D3 when viewed in a plan view. The first cell bonding region 410 and/or the second cell bonding region 420 may be disposed in the spaces between the third cell bonding regions 430 in the grid pattern, e.g., between adjacent ones of the plurality of third cell bonding regions 430. For example, the third cell bonding regions 430 may be disposed in such a manner that a border of the third cell bonding region 430 is adjacent to the first cell bonding region 410 and the second cell bonding region 420. However, the form and the size of the third cell bonding region 430 are not limited to the above description and the drawings.

In some implementations, the cell bonding metal layer 400 may include third cell bonding metals (or metal portions) 431 disposed in each of the third cell bonding regions 430. The third cell bonding metals 431 may be disposed in a plural number on the third cell bonding region 430. The third cell bonding metal 431 may be connected to the peripheral bonding metal layer 500 and may be formed of copper (Cu). However, this is merely an example, and the third cell bonding metal 431 may also be formed of other various metals such as aluminum (Al) or tungsten (W). The third cell bonding metals 431 may be discrete portions of metal that are discontinuous from one another.

In some implementations, the third cell bonding metals 431 may be arranged two-dimensionally within the third cell bonding region 430 (e.g., forming a two-dimensional array, or other two-dimensional pattern). The third cell bonding metals 431 may be disposed to be spaced apart from each other within the third cell bonding region 430. For example, at least some of the third cell bonding metals 431 may be disposed at a third interval a3 along the second direction D2 and disposed at a predetermined interval along the third direction D3.

In some implementations, at least some of the third cell bonding metals 431 may be disposed in a zigzag or staggered manner along the second direction D2. For example, some of the third cell bonding metals 431 may be disposed to be staggered along the second direction D2. As the third cell bonding metals 431 are disposed to be staggered, an area of a portion occupied by the third cell bonding metal 431 in the third cell bonding region 430 may decrease. Due to this, a ratio of an area of the plurality of third cell bonding metals 431 to an area of the third cell bonding region 430 may be less than a ratio of an area of the plurality of first cell bonding metals 411 to an area of the first cell bonding region 410. Accordingly, when the cell array region CAR is observed through a TEM, the third cell bonding region 430 may appear fainter on the cell array region CAR than the first cell bonding region 410. The bonding metals 411 and 431 of the first cell bonding region 410 and the third cell bonding region 430 may form respective pluralities of horizontal patterns parallel to the second direction D2 on the cell array region CAR, the horizontal patterns spaced apart at a predetermined interval along the third direction D3. Since the third cell bonding metals 431 are disposed in a zigzag manner (e.g., and as a result of a difference between the densities of the bonding metals 411 and 431 of the first cell bonding region 410 and the third cell bonding region 430), an interval between the third cell bonding metals 431 adjacent in an identical or horizontal line may increase or may be larger than an interval between the first cell bonding metals 411 adjacent in an identical or horizontal line. Accordingly, a defect may arise in the manufacturing process of forming the cell bonding metal layer 400. To prevent or reduce occurrence of these defects, the third interval a3 may be smaller than the first interval a1.

In some implementations, the plurality of horizontal patterns formed by the third cell bonding metals 431 of the third cell bonding regions 430 may be parallel to the second direction D2. The plurality of horizontal patterns may be disposed to be spaced apart from each other along the third direction D3.

In some implementations, multiple bonding metals (or metal portions) 411, 421, 431, and 441 (e.g., so many that it may be difficult or impossible to count them manually) may be included in the cell array region CAR. The plurality of vertical patterns formed by the second cell bonding regions 420 (or by the second cell bonding metals 421) and the plurality of horizontal patterns formed by the third cell bonding regions 430 (or by the third cell bonding metals 431) may be a reference point that enables a worker to rapidly count or identify a specific point in the cell array region CAR. For example, when a defect arises at a specific point in the cell array region CAR, the point of the defect may be counted and defined as an N-th of the second cell bonding regions 420 and an M-th of the third cell bonding regions 430. The N-th of the second cell bonding regions 420 and/or the M-th of the third cell bonding regions 430 may be identified using distinct/identifying (e.g., unique) arrangements of the second cell bonding metals 421 and/or third cell bonding metals 431 in each of the second cell bonding regions 420 and/or third cell bonding regions 430.

In some implementations, based on the above description, the cell array region CAR may include a pattern recognized using a difference between the density of the second cell bonding metal 421 to the second cell bonding region 420 and the density of the third cell bonding metal 431 to the third cell bonding region 430.

The arrangement of the cell bonding metals 411, 421, and 431 formed in the cell array region CAR is not limited to the above description. For example, the density of the second cell bonding metal 421 to the second cell bonding region 420 and/or the density of the third cell bonding metal 431 to the third cell bonding region 430 may also be greater than the density of the first cell bonding metal 411 to the first cell bonding region 410. For example, the second interval a2 and/or the third interval a3 may be greater than the first interval a1. For example, the second cell bonding region 420 and/or the third cell bonding region 430 may also be a vacant region where bonding metals are not disposed. It is sufficient that the cell bonding metal layer 400 may be formed in such a manner that the cell structure CELL and the peripheral circuit structure PERI are stably coupled, the electrical connection between the cell structure CELL and the peripheral circuit structure PERI is formed and stable, and a reference point for locating a defect may be counted. In other words, the intervals, the size, and the shape of the bonding metals 411, 421, 431, and 441 may be modified freely in accordance with these and the other principles provided herein.

In some implementations, the peripheral bonding metal layer 500 may be symmetrical to the cell bonding metal layer 400 with respect to a bonding surface BS. However, a portion of the peripheral bonding metal layer 500 may not be symmetrical to the cell bonding metal layer 400. For example, the peripheral bonding metal layer 500 may include a first peripheral bonding metal corresponding to the first cell bonding metal 411, a second peripheral bonding metal corresponding to the second cell bonding metal 421, and a third peripheral bonding metal corresponding to the third cell bonding metal 431. For example, when the configurations of the peripheral bonding metal layer 500 are symmetrical to the cell bonding metal layer 400, the peripheral bonding metals may include a pattern with an identical shape to FIG. 6.

In some implementations, the first peripheral bonding metal, the second peripheral bonding metal, and the third peripheral bonding metal may be electrically isolated from the peripheral circuit substrate 200. The peripheral bonding metal layer 500 may include a configuration corresponding to the channel bonding metal 441. The configuration corresponding to the channel bonding metal 441 may also be electrically connected to the peripheral circuit substrate 200.

FIG. 7 is a diagram illustrating a portion of a cell bonding metal layer 610, 620, 630 of an example of the semiconductor memory device 10. Specifically, FIG. 7 is a diagram illustrating second cell bonding metals of second cell bonding regions 620 disposed N-th is disposed in a pattern that indicates being N-th of the second cell bonding region 620. First cell bonding regions 610 and second cell bonding regions 620 may be disposed alternately, e.g., along the second direction D2.

In some implementations, each line parallel to the third direction D3 in each of the second cell bonding regions 620 may represent each number of digits of N. For example, based on the illustration in FIG. 7, the second cell bonding region 620 disposed first from the left may represent 1, the second cell bonding region 620 disposed second from the left may represent 2, the second cell bonding region 620 disposed third from the left may represent 3, the second cell bonding region 620 disposed fourth from the left may represent 23, and the second cell bonding region 620 disposed fifth from the left may represent 24. For example, second cell bonding regions 620 representing numbers 4 to 22 may be disposed between the second bonding region 620 representing 3 and the second bonding region 620 representing 23. Likewise, one or more second cell bonding regions 620 representing numbers incrementally greater than 24, such as 25 and beyond, may be disposed after the region representing 24. The second cell bonding region 620 representing 1 may be a first of the second cell bonding region 620 located at an end of the cell bonding metal layers 610, 620, 630 among a plurality of second cell bonding regions 620. However, a pattern that indicates being disposed N-th from the first of the second cell bonding region 620 is not limited thereto. For example, various manners such as a base-n number system and a manner of directly printing numbers on a substrate may be used.

In some implementations, similarly to the description provided for the second cell bonding regions 620 for FIG. 7, a third cell bonding metals may also be disposed in a pattern indicating an identity of index of each of the third cell bonding regions, e.g., in an index with respect to a first of the third cell bonding region (not shown). For example, different third cell bonding regions may include third cell bonding metals disposed in different patterns. As such, an index or identity of each of the third cell bonding regions can be identified more readily. For example, an M-th of the third cell bonding regions can have a pattern of third cell bonding metals that indicates that the M-th third cell bonding region is the M-th third cell bonding region (e.g., in a sequence starting with a first third cell bonding region).

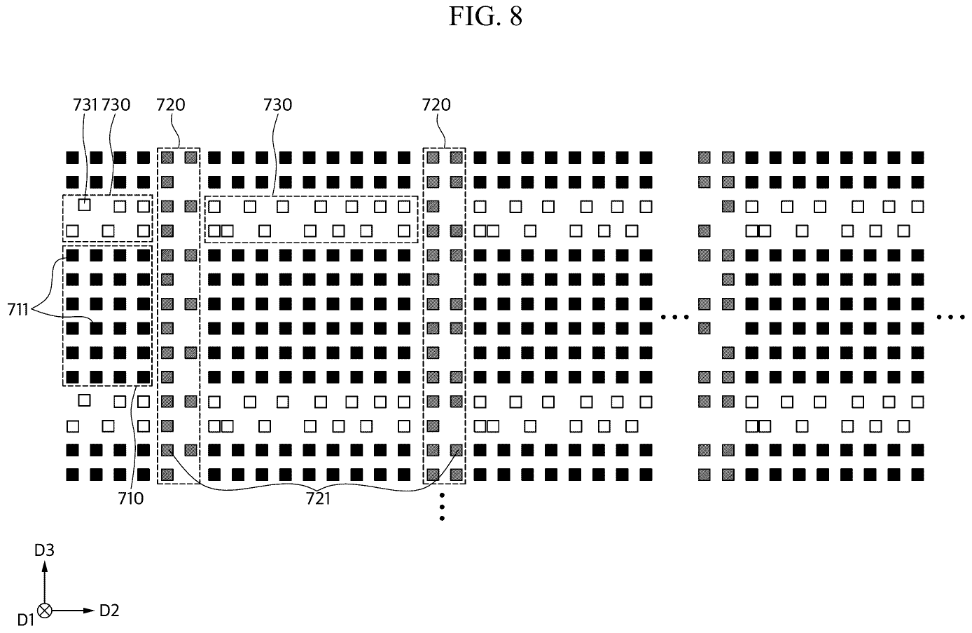

FIG. 8 is a diagram illustrating a portion of an example of cell bonding metal layers 710, 720, 730 of the semiconductor memory device 10.

In some implementations, the cell bonding metal layer 710, 720, 730 may include a first cell bonding region 710, a second cell bonding region 720, and a third cell bonding region 730. First cell bonding metals 711 of the first cell bonding region 710 may be disposed at a predetermined interval. Third cell bonding metals 731 of the third cell bonding region 730 may be disposed in a pattern described with respect to FIG. 6.

FIG. 8 is provided to illustrate a combination of various manners of arrangements of bonding metals 711, 721, 731. As shown in FIG. 8, the first cell bonding region 710, the second cell bonding region 720, and the third cell bonding region 730 may include various manners of patterns that may provide a reference point for defining a specific point in the cell array region CAR. In addition, it is illustrated in the drawings that the second cell bonding region 720 extends along the third direction D3 and the third cell bonding region 730 extends along the second direction D2, but the present disclosure is not limited thereto.

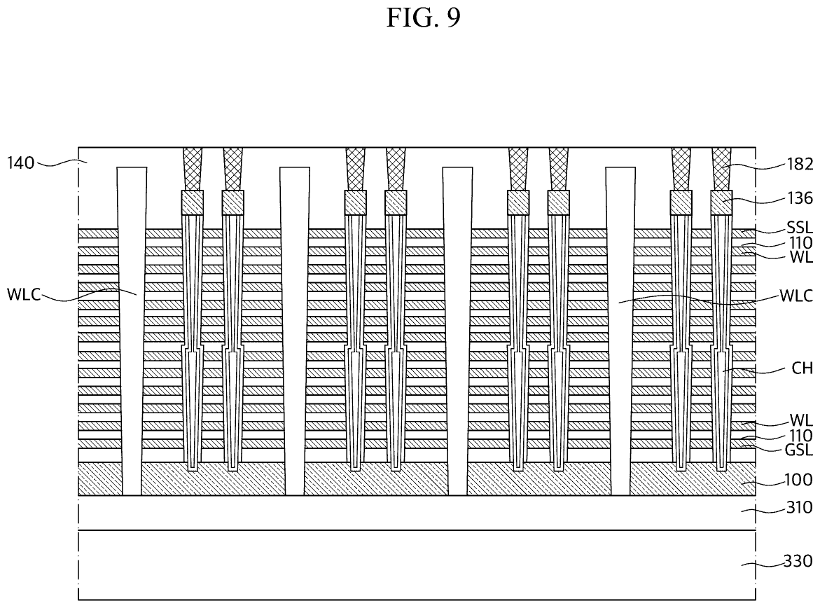

FIGS. 9 to 15 are diagrams showing intermediate stages for illustrating an example of a method of manufacturing the semiconductor memory device 10.

Referring to FIG. 9, the semiconductor memory device 10 may include the cell substrate 100 and the first interlayer insulating layer 140 disposed on the cell substrate 100. The semiconductor memory device 10 may include the plurality of mold insulating layers 110 stacked alternately above the cell substrate 100 and the plurality of gate electrodes GSL, WL, and SSL disposed therebetween.

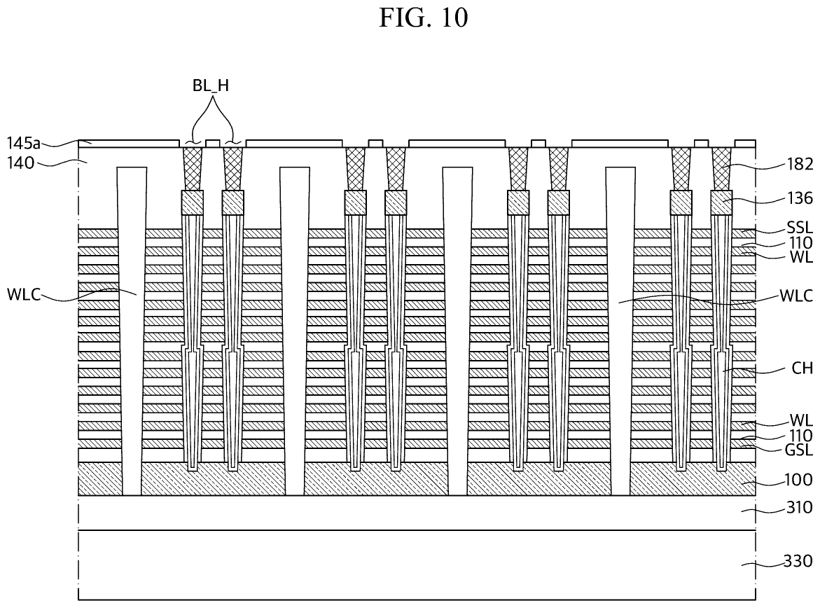

Referring to FIG. 10, in a manufacturing process of the cell structure CELL, a first pre-insulating layer 145a may be formed. The first pre-insulating layer 145a may be a portion of the first interwiring insulating layer 145. The first pre-insulating layer 145a may form a bit line hole BL_H. The bit line hole BL_H may be formed on the first interlayer insulating layer 140.

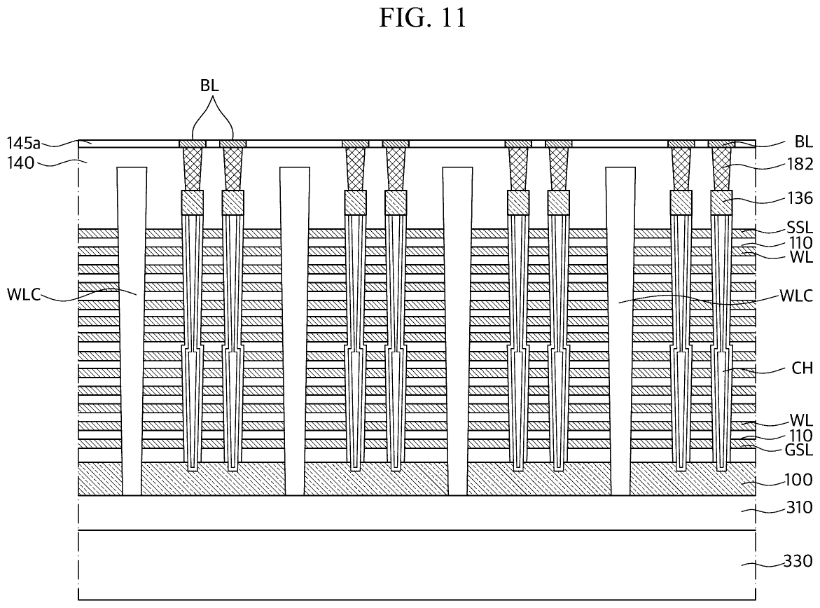

Referring to FIG. 11, in the manufacturing process of the cell structure CELL, the bit line BL may be formed. The bit line BL may be disposed at the bit line hole BL_H. The bit line BL may be electrically connected to the bit line contact 182.

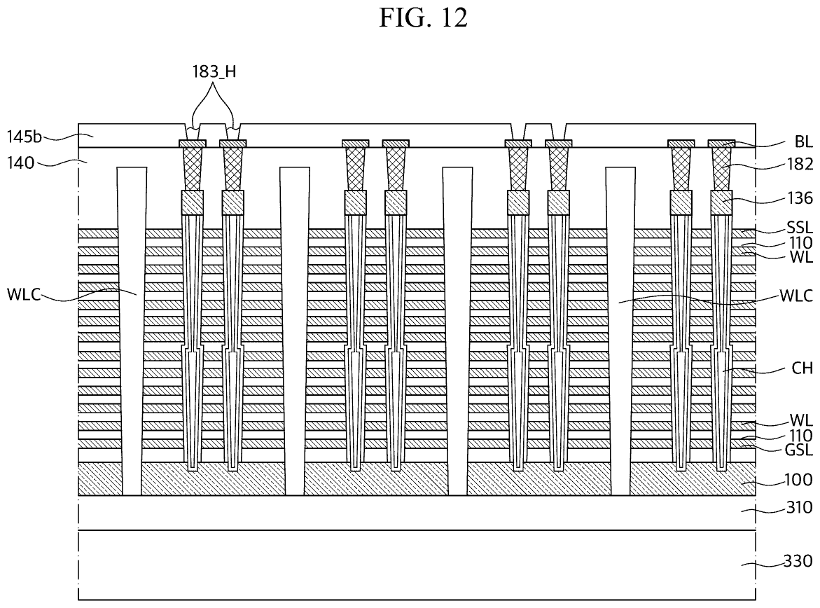

Referring to FIG. 12, in the manufacturing process of the cell structure CELL, a second pre-insulating layer 145b may be formed. The second pre-insulating layer 145b may be a portion of the first interwiring insulating layer 145. The second pre-insulating layer 145b may form a bonding via hole 183_H. The bonding via hole 183_H may be formed to correspond to some of the bit lines BL. The second pre-insulating layer 145b may cover the bit line BL of a portion where the bonding via hole 183_H is not formed.

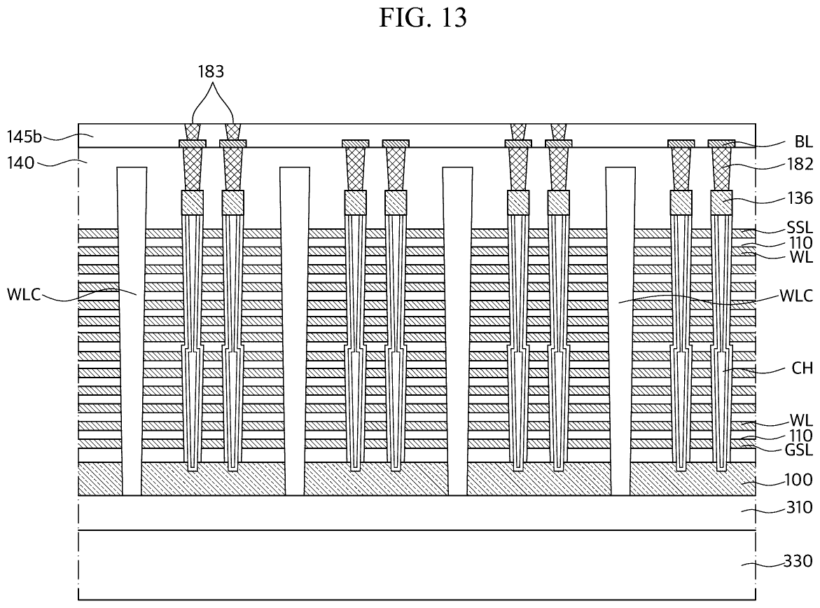

Referring to FIG. 13, in the manufacturing process of the cell structure CELL, the bonding via 183 may be formed. The bonding via 183 may be electrically connected to the bit line BL in contact with the bonding via 183.

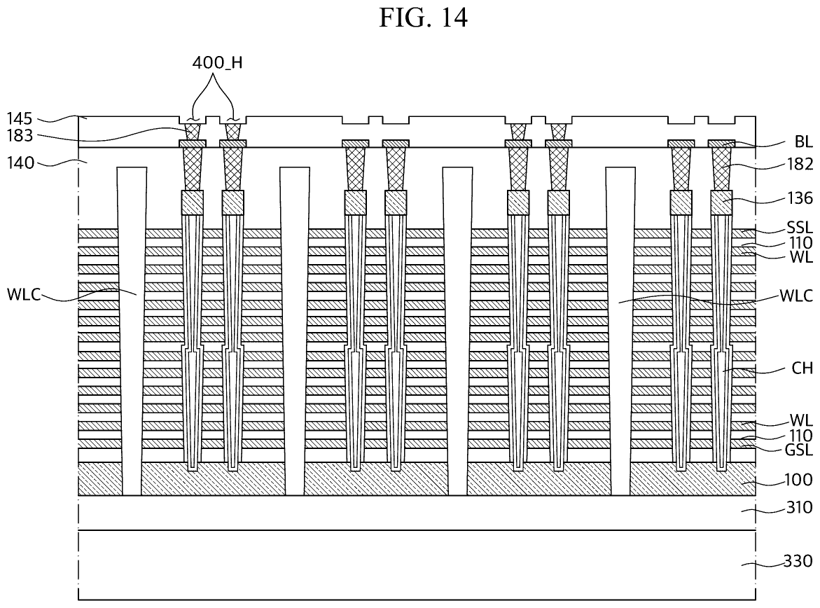

Referring to FIG. 14, in the manufacturing process of the cell structure CELL, the first interwiring insulating layer 145 may be formed. The first interwiring insulating layer 145 may form a cell bonding metal hole 400_H. The cell bonding metal hole 400_H may be formed to correspond to the bonding via 183.

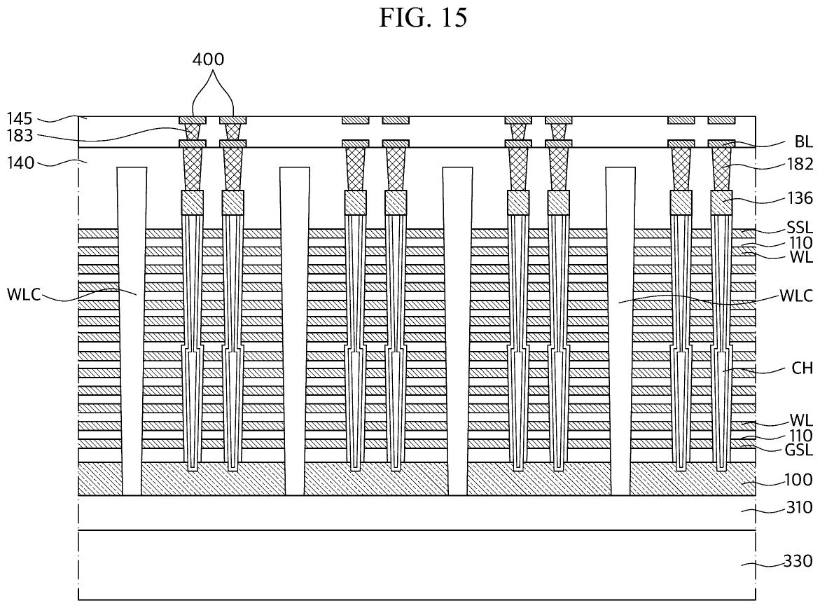

Referring to FIG. 15, in the manufacturing process of the cell structure CELL, the cell bonding metal layer 400 including the bonding metals 411, 421, 431, and 441 may be formed. Some 441 of the bonding metals of the cell bonding metal layer 400 may be electrically connected to the bit line BL through the bonding via 183. Some 411 and 421 of the bonding metals of the cell bonding metal layer 400 may be electrically isolated from the bit line BL.

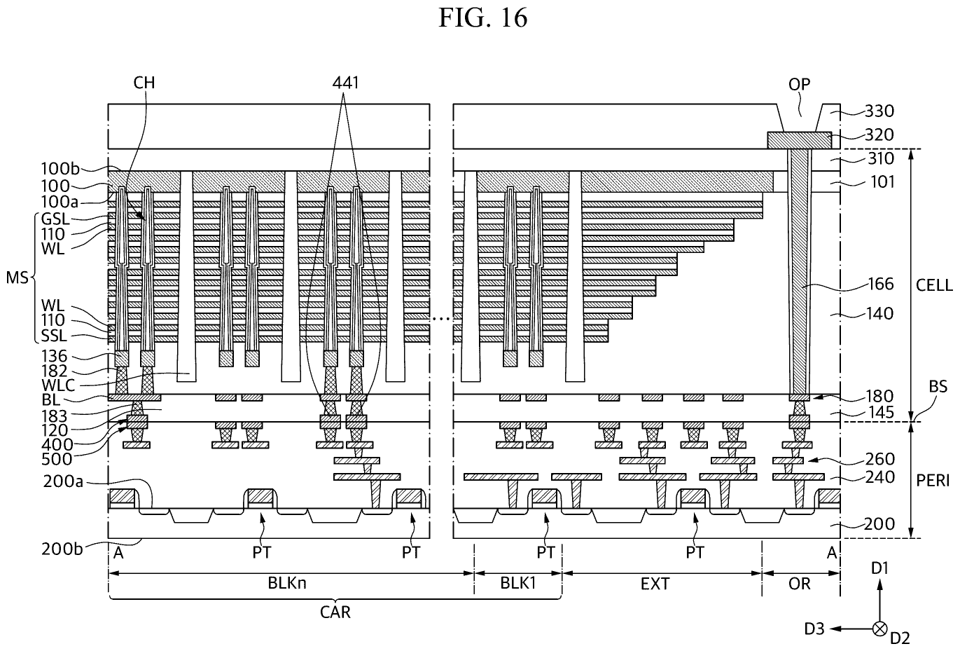

FIG. 16 is a diagram illustrating a cross-section of a portion of an example of the semiconductor memory device 10.

Referring to FIG. 16, the bonding via 183 and the bonding metal of the cell bonding metal layer 400 of the semiconductor memory device 10 may be disposed only at a portion where the channel structure CH is connected to the bit line BL through the bit line contact 182.

In some implementations, similarly to the bonding metal of the cell bonding metal layer 400, the bonding metal of the peripheral bonding metal layer 500 may also be disposed only at a location corresponding to the portion where the channel structure CH is connected to the bit line BL through the bit line contact 182.

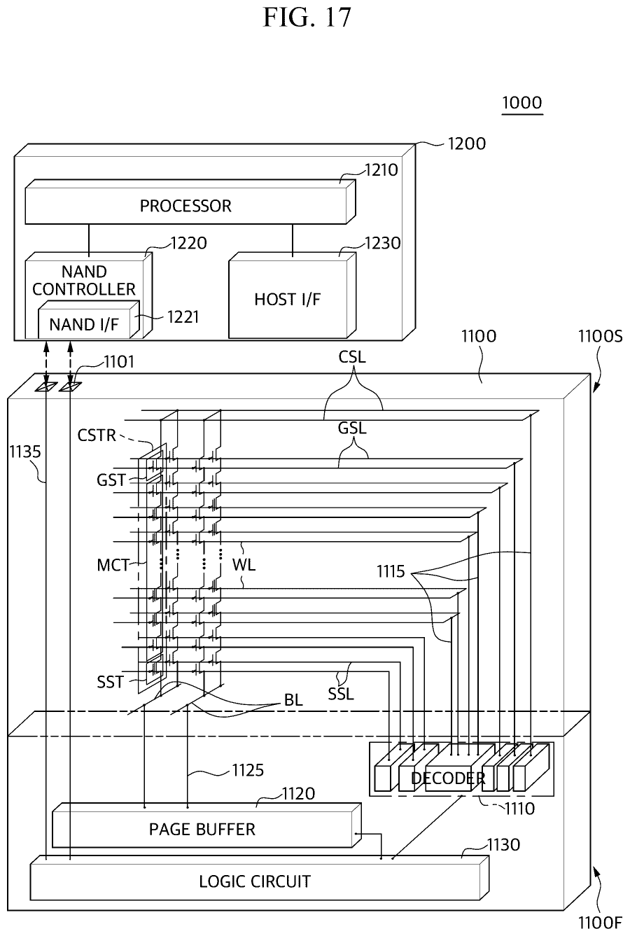

FIG. 17 is a diagram for illustrating an electronic system that can include a semiconductor memory device as described herein.

Referring to FIG. 17, an electronic system 1000 may include a semiconductor memory device 1100 and a controller 1200 electrically connected to the semiconductor memory device 1100. The electronic system 1000 may be a storage device including one or a plurality of semiconductor memory devices 1100 or an electronic device including the storage device. For example, the electronic system 1000 may be a solid-state drive (SSD) device, a universal serial bus (USB), a computing system, a medical device, or a communication device including one or the plurality of semiconductor memory devices 1100.

In some implementations, the semiconductor memory device 1100 may be a non-volatile memory device (for example, a NAND flash memory device) and, for example, the semiconductor memory device 1100 may be the semiconductor memory device 10 described above with reference to the drawings. The semiconductor memory device 1100 may include a first structure 1100F and a second structure 1100S on the first structure 1100F.

In some implementations, the first structure 1100F may be a peripheral circuit structure including a decoder circuit 1110 (for example, the row decoder 33 of FIG. 1), a page buffer 1120 (for example, the page buffer 35 of FIG. 1), and a logic circuit 1130 (for example, the control logic 37 of FIG. 1). For example, the first structure 1100F may correspond to the peripheral circuit structure PERI.

In some implementations, the second structure 1100S may include the common source line CSL, the plurality of bit lines BL, and the plurality of cell strings CSTR described above with reference to FIG. 2. The cell strings CSTR may be connected to the decoder circuit 1110 through the word line WL, at least one string selection line SSL, and at least one ground selection line GSL. In addition, the cell strings CSTR may be connected to the page buffer 1120 through the bit lines BL. For example, the second structure 1100S may correspond to the cell structure CELL described above with reference to the drawings.

In some implementations, the common source line CSL and the cell strings CSTR may be electrically connected to the decoder circuit 1110 through first connection wirings 1115 extending from the first structure 1100F to the second structure 1100S. The bit lines BL may be electrically connected to the page buffer 1120 through second connection wirings 1125 extending from the first structure 1100F to the second structure 1100S.

In some implementations, the semiconductor memory device 1100 may communicate with the controller 1200 through an input/output pad 1101 electrically connected to the logic circuit 1130 (for example, the control logic 37). The input/output pad 1101 may be electrically connected to the logic circuit 1130 through an input/output connection wiring 1135 extending to the second structure 1100S within the first structure 1100F. The input/output pad 1101 may correspond to the input/output pad 320 described above with reference to the drawings. For example, the input/output connection wiring 1135 may correspond to the contact plug 166 described above with reference to the drawings.

In some implementations, the controller 1200 may include a processor 1210, a NAND controller 1220, and a host interface 1230. The electronic system 1000 may include the plurality of semiconductor memory devices 1100 and, in this case, the controller 1200 may control the plurality of semiconductor memory devices 1100.

In some implementations, the processor 1210 may control the overall operation of the electronic system 1000 including the controller 1200. The processor 1210 may operate based on predetermined firmware and may control the NAND controller 1220 to access the semiconductor memory device 1100. The NAND controller 1220 may include a NAND interface 1221 that processes communication with the semiconductor memory device 1100. Through the NAND interface 1221, a control instruction for controlling the semiconductor memory device 1100, data to be recorded in the memory cell transistors MCT of the semiconductor memory device 1100, and data to be read from the memory cell transistors MCT of the semiconductor memory device 1100 may be transmitted. The host interface 1230 may provide a communication function between the electronic system 1000 and an external host. When a control instruction is received from the external host through the host interface 1230, the processor 1210 may control the semiconductor memory device 1100 in response to the control instruction.

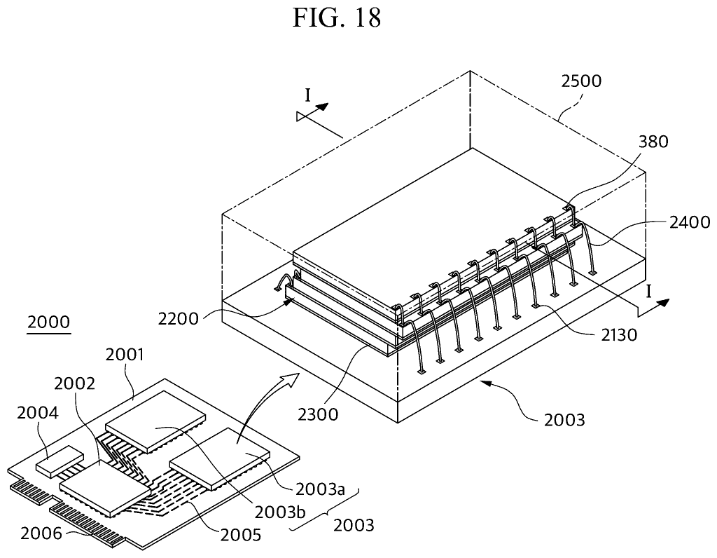

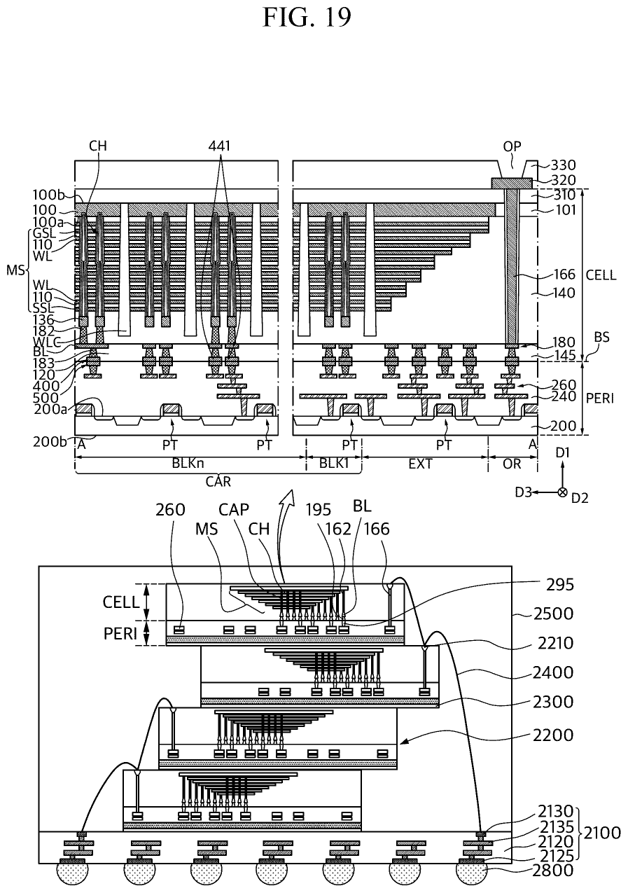

FIG. 18 is a perspective view for illustrating an electronic system that can include a semiconductor memory device as described herein, and FIG. 19 is a diagram illustrating an example of a cross-section taken along line I-I of FIG. 18.

Referring to FIGS. 18 and 19, an electronic system may include a main substrate 2001, a main controller 2002 mounted on the main substrate 2001, one or more semiconductor packages 2003, and dynamic random access memory (DRAM) 2004. The semiconductor package 2003 and the DRAM 2004 may be mutually connected to the main controller 2002 by wiring patterns 2005 formed on the main substrate 2001.

In some implementations, the main substrate 2001 may include a connector 2006 including a plurality of pins coupled to an external host. The number and arrangement of the plurality of pins in the connector 2006 may vary depending on a communication interface between an electronic system 2000 and the external host. In some implementations, the electronic system 2000 may communicate with the external host based on one of interfaces such as universal serial bus (USB), peripheral component interconnect express (PCI-Express), serial advanced technology attachment (SATA), and M-Phy for universal flash storage (UFS). In some implementations, the electronic system 2000 may operate by power supplied from the external host through the connector 2006. The electronic system 2000 may further include a power management integrated circuit (PMIC) that distributes power supplied from the external host to the main controller 2002 and the semiconductor package 2003.

In some implementations, the main controller 2002 may record data in the semiconductor package 2003 or read data from the semiconductor package 2003 and may improve the operation speed of the electronic system 2000.

In some implementations, the DRAM 2004 may be buffer memory for mitigating a speed difference between the semiconductor package 2003 which is a data storage space and the external host. The DRAM 2004 included in the electronic system 2000 may operate as a type of cache memory and may also provide a space for storing data temporarily in a control operation for the semiconductor package 2003. When the electronic system 2000 includes the DRAM 2004, the main controller 2002 may further include a DRAM controller for controlling the DRAM 2004 in addition to a NAND controller for controlling the semiconductor package 2003.

In some implementations, the semiconductor package 2003 may include a first semiconductor package 2003a and a second semiconductor package 2003b spaced apart from each other. Each of the first semiconductor package 2003a and the second semiconductor package 2003b may be a semiconductor package including a plurality of semiconductor chips 2200. Each of the first semiconductor package 2003a and the second semiconductor package 2003b may include a package substrate 2100, the semiconductor chips 2200 on the package substrate 2100, a bonding layer 2300 disposed on a lower surface of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

In some implementations, the package substrate 2100 may be a printed circuit board including package upper pads 2130. Each of the semiconductor chips 2200 may include an input/output pad 2210.

In some implementations, the connection structure 2400 may be a bonding wire electrically connecting the input/output pad 2210 and the package upper pads 2130. Therefore, in each of the first semiconductor package 2003a and the second semiconductor package 2003b, the semiconductor chips 2200 may be electrically connected to each other in a bonding wire manner and may be electrically connected to the package upper pads 2130 of the package substrate 2100. In some implementations, in each of the first semiconductor package 2003a and the second semiconductor package 2003b, the semiconductor chips 2200 may also be electrically connected to each other by a connection structure including a through silicon via (TSV) instead of the connection structure 2400 with the bonding wire manner.

In some implementations, the main controller 2002 and the semiconductor chips 2200 may also be included in one package. In some implementations, the main controller 2002 and the semiconductor chips 2200 may be mounted on a separate interposer substrate other than the main substrate 2001, and the main controller 2002 and the semiconductor chips 2200 may also be connected to each other by wiring formed on the interposer substrate.

In some implementations, the package substrate 2100 may be a printed circuit board. The package substrate 2100 may include a package substrate body part 2120, the package upper pads 2130 disposed on an upper surface of the package substrate body part 2120, lower pads 2125 disposed on a lower surface of the package substrate body part 2120 or exposed through the lower surface, and internal wirings 2135 electrically connecting the upper pads 2130 and the lower pads 2125 within the package substrate body part 2120. The upper pads 2130 may be electrically connected to the connection structures 2400. The lower pads 2125 may be connected to the wiring patterns 2005 of the main substrate 2001 of the electronic system 2000 as in FIG. 18 through conductive connection parts 2800.

In some implementations, each of the semiconductor chips 2200 may include the semiconductor memory device described above with reference to the drawings. In the electronic system, when a signal is inputted to and outputted from the semiconductor memory device of the semiconductor chips 2200, a noise of input/output signals may be mitigated using the capacitor structure CAP.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While various examples are described in detail above, the scope of the present disclosure is not limited thereto, and it will be apparent to those of ordinary skill in the art that modifications and variations may be made without departing from the scope of the present disclosure. In addition, the aforementioned implementations may be implemented with some elements removed, and each example may be implemented in combination with each other.

What is claimed is:

1. A semiconductor memory device comprising:
a cell structure comprising:
a cell substrate,
a mold structure including a plurality of gate electrodes stacked in a first direction on the cell substrate,
a channel structure extending in the mold structure in the first direction, and
a cell bonding metal layer disposed below the mold structure in the first direction; and
a peripheral circuit structure that includes a peripheral circuit substrate and a peripheral bonding metal layer that is connected to the cell bonding metal layer, wherein the peripheral circuit structure is located above the peripheral circuit substrate in the first direction and is connected to the cell structure at a bonding surface,
wherein the cell bonding metal layer includes:
a plurality of first cell bonding regions, wherein each of the plurality of first cell bonding regions includes a plurality of first cell bonding metal portions disposed at a first interval along a second direction intersecting with the first direction, and
a plurality of second cell bonding regions, wherein each of the plurality of second cell bonding regions includes a plurality of second cell bonding metal portions disposed at a second interval, different from the first interval, along the second direction, and
wherein the plurality of first cell bonding regions and the plurality of second cell bonding regions are disposed alternately along the second direction.

2. The semiconductor memory device of claim 1, wherein the plurality of first cell bonding metal portions are electrically isolated from the channel structure, and
wherein the plurality of second cell bonding metal portions are electrically isolated from the channel structure.

3. The semiconductor memory device of claim 2, wherein the second interval is smaller than the first interval.

4. The semiconductor memory device of claim 3, wherein the plurality of second cell bonding metal portions comprises a first subset of second cell bonding metal portions that is staggered, with respect to a second subset of the plurality of second cell bonding metal portions, along a third direction intersecting with the first direction and the second direction.

5. The semiconductor memory device of claim 4, wherein a ratio of an area of a plurality of second cell bonding metal portions in one of the plurality of second cell bonding regions, to an area of the one of the plurality of second cell bonding regions, is less than a ratio of an area of a plurality of first cell bonding metal portions in one of the plurality of first cell bonding regions, to an area of the one of the plurality of first cell bonding regions.

6. The semiconductor memory device of claim 2, wherein the cell bonding metal layer includes a plurality of channel bonding metals disposed below the cell substrate in the first direction and electrically connected to the channel structure.

7. The semiconductor memory device of claim 2, wherein the cell bonding metal layer includes a plurality of third cell bonding regions, wherein each of the plurality of third cell bonding regions includes a plurality of third cell bonding metal portions disposed at a third interval, different from the first interval, along the second direction, and
wherein the plurality of first cell bonding regions and the plurality of third cell bonding regions are disposed alternately along a third direction intersecting with the first direction and intersecting with the second direction.

8. The semiconductor memory device of claim 7, wherein the plurality of third cell bonding metal portions are electrically isolated from the channel structure.

9. The semiconductor memory device of claim 8, wherein the third interval is smaller than the first interval.

10. The semiconductor memory device of claim 9, wherein the plurality of third cell bonding metal portions comprises a first subset of third cell bonding metal portions that are staggered, with respect to a second subset of the plurality of third cell bonding metal portions, along the second direction.

11. The semiconductor memory device of claim 10, wherein a ratio of an area of a plurality of third cell bonding metal portions in one of the plurality of third cell bonding regions, to an area of the one of the plurality of third cell bonding regions, is less than a ratio of an area of a plurality of first cell bonding metal portions in one of the plurality of first cell bonding regions, to an area of the one of the plurality of first cell bonding regions.

12. The semiconductor memory device of claim 2, wherein a plurality of second cell bonding metal portions, disposed in one of the plurality of second cell bonding regions, are arranged in a pattern that indicates an index of the one of the plurality of second cell bonding regions, with respect to a first of the plurality of second cell bonding regions that is located at an end of the cell bonding metal layer along the second direction.

13. The semiconductor memory device of claim 2, wherein the peripheral bonding metal layer includes:
a plurality of first peripheral bonding metals arranged symmetrically to the plurality of first cell bonding metal portions with respect to the bonding surface; and
a plurality of second peripheral bonding metals arranged symmetrically to the plurality of second cell bonding metal portions with respect to the bonding surface.

14. The semiconductor memory device of claim 13, wherein the plurality of first peripheral bonding metals and the plurality of second peripheral bonding metals are electrically isolated from the peripheral circuit substrate.

15. A semiconductor memory device comprising:
a cell structure comprising:
a cell substrate,
a mold structure including a plurality of gate electrodes stacked in a first direction on the cell substrate,
a channel structure extending in the mold structure in the first direction, and
a cell bonding metal layer disposed below the mold structure in the first direction; and
a peripheral circuit structure that includes a peripheral circuit substrate and a peripheral bonding metal layer that is connected to the cell bonding metal layer, wherein the peripheral circuit structure is located above the peripheral circuit substrate in the first direction and is connected to the cell structure at a bonding surface,
wherein the cell bonding metal layer includes:
a plurality of first cell bonding regions, wherein each of the plurality of first cell bonding regions includes a plurality of first cell bonding metal portions disposed at a first predetermined interval along a second direction intersecting with the first direction, and
a plurality of second cell bonding regions, wherein each of the plurality of second cell bonding regions includes a plurality of second cell bonding metal portions disposed at a second predetermined interval along the second direction,
wherein a ratio of an area of a plurality of second cell bonding metal portions in one of the plurality of second cell bonding regions, to an area of the one of the plurality of second cell bonding regions, is less than a ratio of an area of a plurality of first cell bonding metal portions in one of the plurality of first cell bonding regions, to an area of the one of the plurality of first cell bonding regions, and
wherein the plurality of first cell bonding regions and the plurality of second cell bonding regions are disposed alternately along the second direction.

16. The semiconductor memory device of claim 15, wherein the plurality of first cell bonding metal portions are electrically isolated from the channel structure,
wherein the plurality of second cell bonding metal portions are electrically isolated from the channel structure, and
wherein the cell bonding metal layer further includes a plurality of channel bonding metal portions disposed above the cell substrate and electrically connected to the channel structure.

17. The semiconductor memory device of claim 16, wherein the cell bonding metal layer includes a plurality of third cell bonding regions, wherein each of the plurality of third cell bonding regions includes a plurality of third cell bonding metal portions electrically isolated from the channel structure,
wherein the plurality of second cell bonding regions and the plurality of third cell bonding regions are disposed alternately along a third direction intersecting with the first direction and the second direction, and
wherein a ratio of an area of a plurality of third cell bonding metal portions in one of the plurality of third cell bonding regions, to an area of the one of the plurality of third cell bonding regions, is less than a ratio of an area of a plurality of first cell bonding metal portions in one of the plurality of first cell bonding regions, to an area of the one of the plurality of first cell bonding regions.

18. The semiconductor memory device of claim 17, wherein a plurality of second cell bonding metal portions, disposed in one of the plurality of second cell bonding regions, are arranged in a pattern that indicates an index of the one of the plurality of second cell bonding regions, with respect to a first of the plurality of second cell bonding regions that is located at an end of the cell bonding metal layer along the second direction.

19. The semiconductor memory device of claim 18, wherein a plurality of third cell bonding metal portions, disposed in one of the plurality of third cell bonding regions, are arranged in a pattern that indicates an index of the one of the plurality of third cell bonding regions, with respect to a first of the plurality of third cell bonding regions that is located at an end of the cell bonding metal layer along the third direction.

20. A semiconductor memory device comprising:
a cell structure comprising:
a cell substrate,
a mold structure including a plurality of gate electrodes stacked in a first direction on the cell substrate,
a channel structure extending in the mold structure in the first direction, and
a cell bonding metal layer disposed below the mold structure in the first direction; and
a peripheral circuit structure that includes a peripheral circuit substrate and a peripheral bonding metal layer that is connected to the cell bonding metal layer, wherein the peripheral bonding metal layer is located above the peripheral circuit substrate in the first direction and is connected to the cell structure at a bonding surface,
wherein the cell bonding metal layer includes:
a plurality of first cell bonding regions, wherein each of the plurality of first cell bonding regions includes a plurality of first cell bonding metal portions disposed at a first interval along a second direction intersecting with the first direction, wherein the plurality of first cell bonding metal portions are electrically isolated from the channel structure;
a plurality of second cell bonding regions, wherein each of the plurality of second cell bonding regions includes a plurality of second cell bonding metal portions disposed at a second interval, smaller than the first interval, along the second direction, wherein the plurality of second cell bonding metal portions are electrically isolated from the channel structure; and
a plurality of third cell bonding regions, wherein each of the plurality of third cell bonding regions includes a plurality of third cell bonding metal portions disposed at a third interval, smaller than the first interval, along the second direction, wherein the plurality of third cell bonding metal portions are electrically isolated from the channel structure,
wherein the plurality of first cell bonding regions and the plurality of second cell bonding regions are disposed alternately along the second direction, and
wherein the plurality of first cell bonding regions and the plurality of third cell bonding regions are disposed alternately along a third direction intersecting with the first direction and intersecting with the second direction.
